(19) United States
(12) Patent Application Publication
(10) Pub. No.: US 2011/0030996 A1
(43) Pub. Date: Feb. 10, 2011

(54) CIRCUIT SUBSTRATE FOR ELECTRONIC DEVICE

(76) Inventor: Karl S. Weibezahn, Corvalis, OR (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/536,077

(22) Filed: Aug. 5, 2009

(51) Int. Cl. H05K 1/02; B05D 5/12

(52) U.S. Cl. 174/254; 427/98.4

(57) ABSTRACT

In one embodiment, an electronic device comprises a substrate, a plurality of circuit traces on a substrate, wherein at least a subset of the plurality of circuit traces comprise at least one tab trace. A plurality of the tab traces are excised from the substrate, and at least one electronic component is positioned proximate at least one tab trace on the substrate. The electrical component comprises at least one electrical contact on an upper surface of the component. The tab trace is lifted and inverted to establish an electrical connection between an electrically conductive portion of the tab trace and an electrical contact on an upper surface of the at least one electronic component.

### BACKGROUND

Various electrical components may utilize arrays of one or more circuit elements mounted on a flexible substrate and electrically coupled by one or more flexible circuit traces. By way of example, flexible circuits, also sometimes referred to as “flex circuits” are used in electronic device such as cell phones, laptop computers, personal digital assistants (PDAs), and the like. In addition, flex circuits may be useful in high-density electronic assemblies such as photo-electric energy conversion circuitry. Some flex circuit designs include mounted electrical components which have electrical contacts on the upper surface of the component. Electrical connection must be established between circuit traces on the circuit substrate and the electrical contacts on the upper surface of the component. Hence, circuit substrate assemblies and techniques for establishing electrical contact between circuit traces on the circuit substrate and the electrical contacts on the upper surface of the component may find utility.

### BRIEF DESCRIPTION OF THE DRAWINGS

FIG. 1 is a schematic illustration of a circuit substrate for an electronic device, according to embodiments.

FIG. 2 is a flowchart illustrating operations in one embodiment of a method to method to make a circuit substrate for an electronic device.

FIG. 3 is a schematic illustration of a circuit substrate for an electronic device, according to embodiments.

FIG. 4 is a flowchart illustrating operations in one embodiment of a method to method to make a circuit substrate for an electronic device.

FIG. 5 is a schematic illustration of a circuit substrate for an electronic device, according to embodiments.

FIG. 6 is a schematic illustration of a circuit substrate for an electronic device, according to embodiments.

### DETAILED DESCRIPTION

Described herein are circuit substrates for electronic devices, methods for making circuit substrates for electronic devices, and electronic devices comprising such circuit substrates. In some embodiments, the circuit substrates described herein may be formed on a flexible substrate material, which may be distributed as a stand-alone product. In further embodiments, one or more electronic components may be mounted on the circuit substrate and connected to circuit traces on the circuit substrate. Further, methods for making such circuit substrates are described.

In the following description, numerous specific details are set forth to provide a thorough understanding of various embodiments. However, it will be understood by those skilled in the art that the various embodiments may be practiced without the specific details. In other instances, well-known methods, procedures, components, and circuits have not been illustrated or described in detail so as not to obscure the particular embodiments.

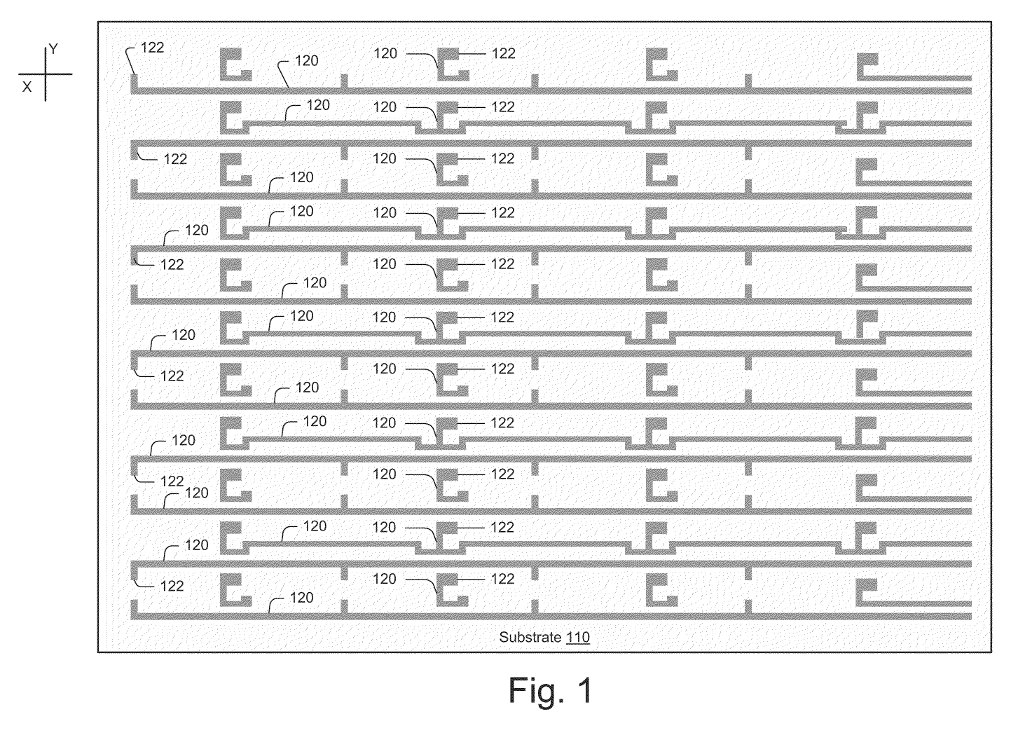

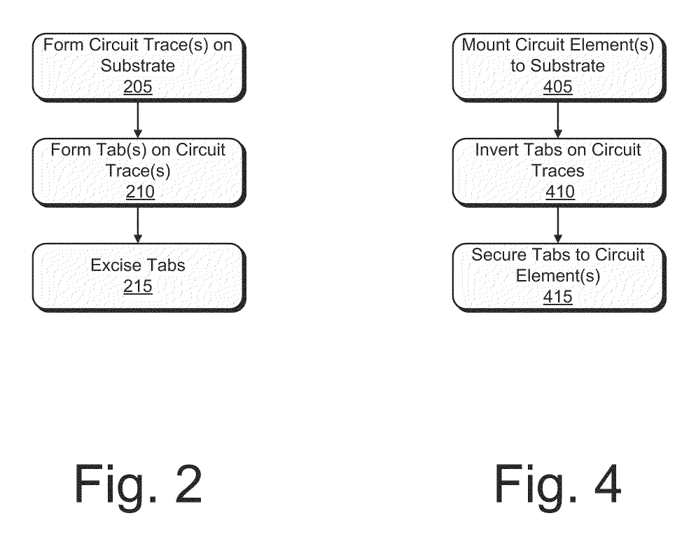

FIG. 1 is a schematic illustration of a circuit substrate for an electronic device, according to embodiments, and FIG. 2 is a flowchart illustrating operations in one embodiment of a method to method to make a circuit substrate for an electronic device. Referring to FIG. 1 and FIG. 2, in one embodiment the circuit substrate comprises a substrate 110, which in turn comprises a number of circuit traces 120. In one embodiment, substrate 110 may be formed from a flexible polymer material which may have originated from a roll form or from a rigid or semi-flexible polymer material which may have originated from a sheet form.

At operation 205 one or more circuit traces (continuous conductors) 120 are patterned on the substrate 110, and at operation 210 one or more tab traces (terminating conductors) 122 are formed on circuit traces 120. Circuit traces 120 and tab traces 122 may be formed by conventional deposition and/or removal techniques. Circuit traces 120 and tab traces 122 may be formed in a single layer on single substrate 110. Alternatively, circuit traces 120 and tab traces 122 may be formed on different layers of a multi-layer substrate 110.

Referring to FIG. 1, one or more of the circuit traces 120 comprise tabbed traces 122 which depend from the circuit trace 120. The embodiment depicted in FIG. 1 comprises an array of circuit traces 120 that have a longitudinal axis that extends along an X-axis of substrate 110.

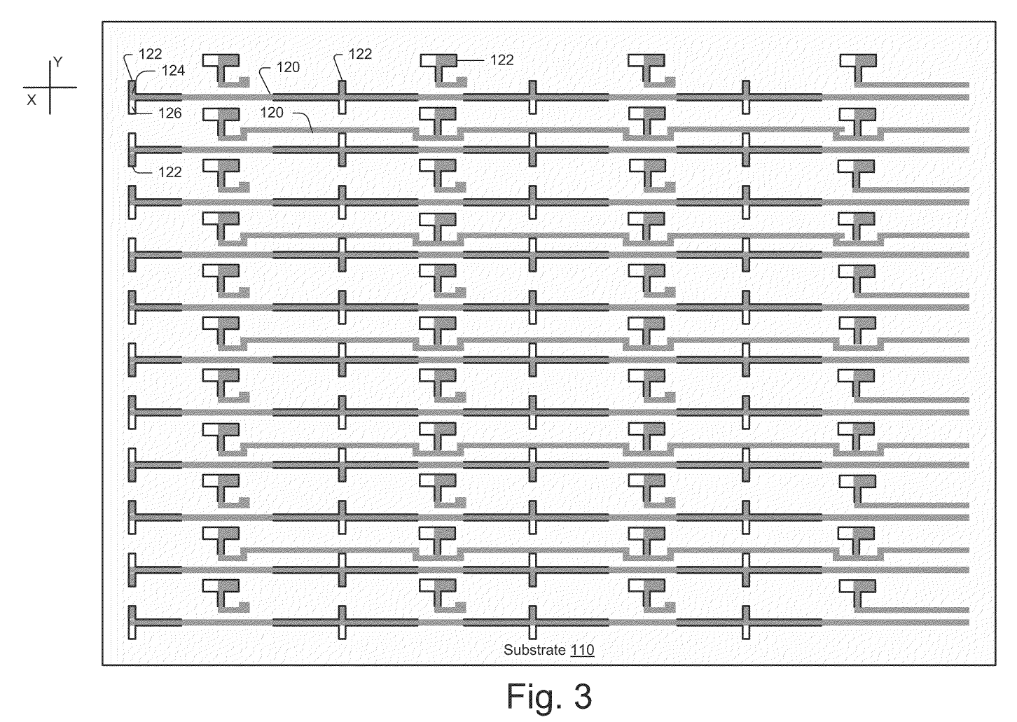

Referring now to FIG. 2 and FIG. 3, at operation 215 one or more tabs 120 are excised. Referring to FIG. 3, the excised portions of the tabs 120 are illustrated by dark black lines. As used herein, the term “excise” refers to a process by which portions of the tabs 122, portions of the circuit trace 120 proximate the tab 122, and portions of the substrate 110 proximate the tab are cut from the substrate 110. In one embodiment, the tab sections 122 may be excised by physically cutting the substrate 110 along the lines indicated in FIG. 3. Alternatively, the tab sections 122 may be excised by cutting the substrate 110 with a laser. The tabbed sections 122 excised from the substrate comprise a conductive section 124 and a non-conductive section 126. The conductive section 124 may comprise a bond pad for securing to a conductive lead of a mounted electrical component.

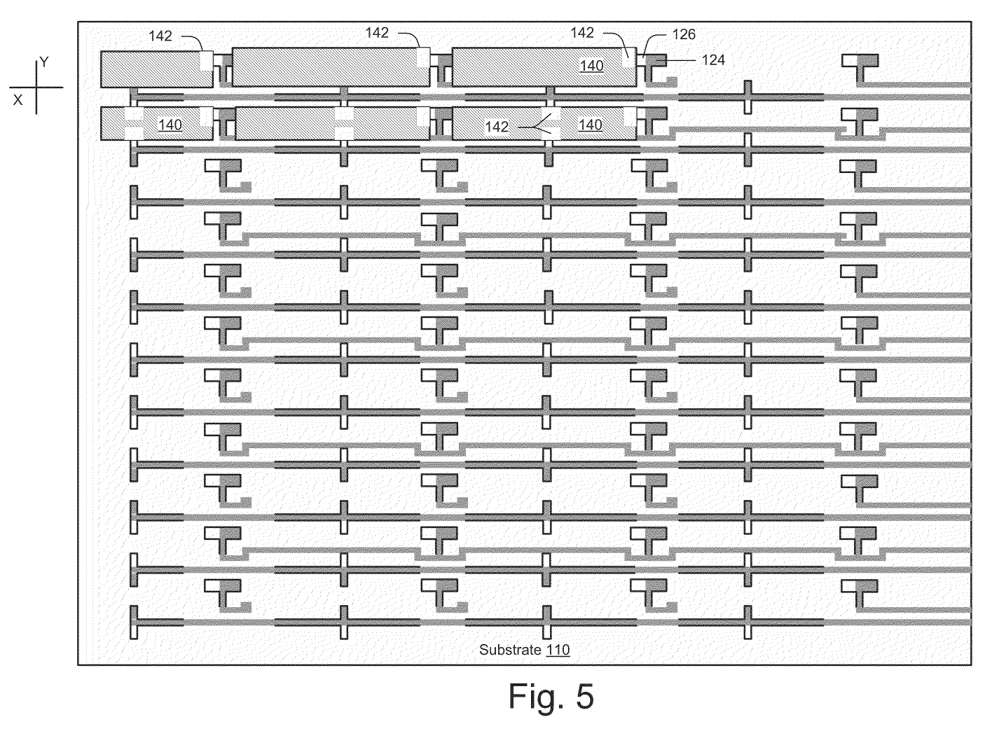

Once the tabbed sections 122 are excised, the sections 122 are free to be lifted from the X-Y plane defined by the substrate 110 or rotated about a longitudinal axis of the circuit trace 120. FIG. 4 is a flowchart illustrating operations in one embodiment of a method to method to make a circuit substrate for an electronic device, and FIG. 5 is a schematic illustration of a circuit substrate for an electronic device, according to embodiments.

Referring to FIG. 4 and FIG. 5, at operation 405 one or more mounted components 140 are positioned/mounted proximate at least one tab traces 122 of the substrate. In the embodiment depicted in FIG. 5, the mounted components 140A depict the circuit substrate after operation 405. The mounted component 140A on the upper row of mounted components is positioned such that the electrical contact 142 is above the non-conductive portion 126 of the tab 122. Similarly, the mounted component 140A on the lower row of mounted components is positioned such that the electrical contacts 142 on the mounted components 140 are positioned above non-conductive portions 126 of tabs 122. While FIG. 5 depicts six mounted components 140 positioned on the substrate 110, one skilled in the art will recognize that the more mounted components 140 or fewer mounted components 140 could be so positioned on the substrate 110. In one embodiment, the entire substrate 110 is covered with mounted components 140.

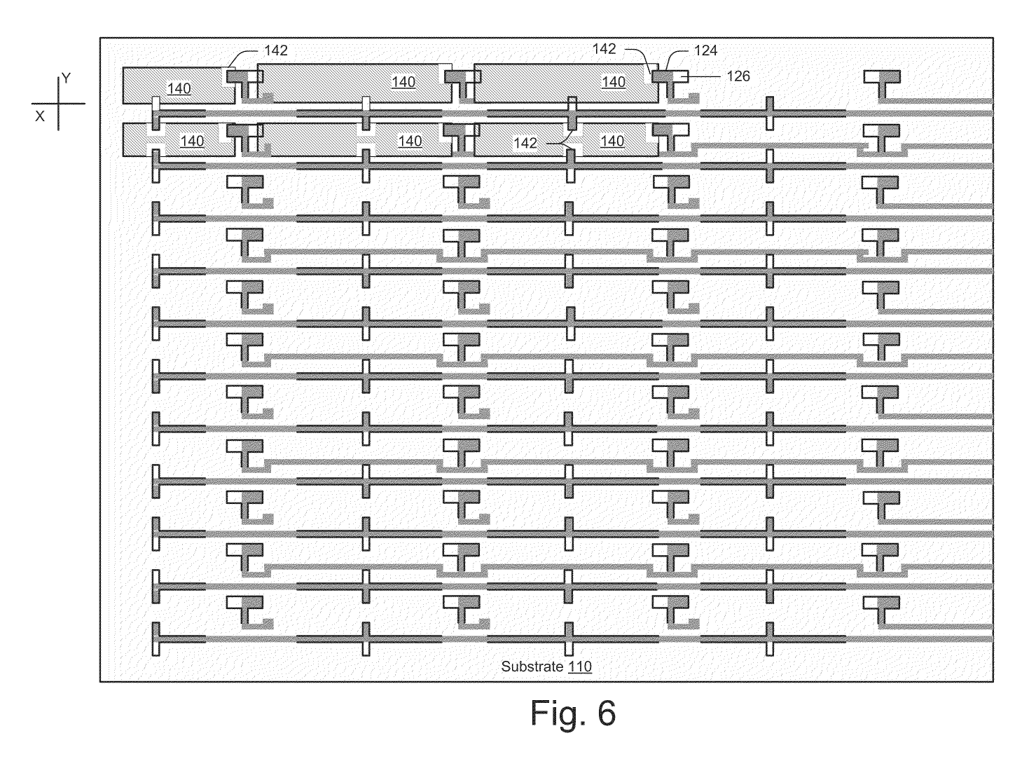

At operation 410 one or more tab traces 122 are lifted and inverted. In one embodiment, the tab traces 122 are manually manipulated with hand tools. In another embodiment, the substrate 110 may be positioned on a platen which comprises a “bed of nails” of recessed lifting pins aligned with the excised tab traces 122. When the pins are raised from the platen, the tab traces 122 are raised from the X-Y plane of the substrate 110, which causes the tab traces 122 to hit the mounted components 140 mounted on the substrate 110. In one embodiment the tab traces 122 are pressed upward at an angle, such that continued lifting of the tab traces 122 causes the tab traces 122 to rotate 180 degrees about a longitudinal axis of the circuit traces 120 to which the tab traces 122 are connected as the tabs clear the upper surface of the mounted components 140. Thus, referring to FIG. 6, the conductive portions 124 of the tab traces 122 are positioned above the mounted component 140 and in contact with the electrical contacts 142 of the mounted components. Similarly, the non-conductive portion 126 of the tab trace 122 is positioned above the adjacent mounted component such that the non-conductive portion 126 facilitates securing the conductive portion 126 to the mounted component 140. Again, while FIG. 5 depicts six mounted components 140 positioned on the substrate 110, one skilled in the art will recognize that the more mounted components 140 or fewer mounted components 140 could be so positioned on the substrate 110. In one embodiment, the entire substrate 110 is covered with mounted components 140.

In some embodiments, the substrate 110 may be implemented as a continuous roll of material, and the platen may be implemented on a patterned roller, such that the substrate rolls over the patterned roller to lift the tab traces 122 in a continuous process. Also, in some embodiments the tab traces 122 may be covered with conductive material on their underside, or lower surfaces. In such embodiments, the tab trace need not rotate 180 degrees about an axis when the tab section is lifted above the mounted component 140. Further, in some embodiments “dummy” tab traces which do not provide electrical connections may be used to facilitate securing the mounted components 140 to the substrate 110.

Further processing may be performed when the conductive portion 126 of the tab traces 122 are positioned above the electrical contacts 142 of the mounted components. Thus, at operation 415 the conductive portion 126 of the tab traces 122 may be secured to the mounted components 140. For example, in some embodiments the conductive portion 126 of the tab traces 122 may comprise a solder ball or a solder coating. Alternatively, or in addition, portions of the upper surface of the mounted components 140 may be coated with a curable adhesive. In such embodiments, the assembly may be heated to melt the solder and/or adhesive, thereby further securing the electrical connection between the electrical contact 142 and the conductive portion 126 of the tab trace 122. In other embodiments additional layers may be positioned above the circuit elements. For example, a protective polymer layer may be positioned above the assembly.

In one embodiment the electrical components 140 may comprise photovoltaic (PV) elements. In such embodiments, the entire substrate 110 may be densely covered with PV elements 140 to yield a solar collector assembly. In such embodiments, the non-conductive portions 124 of the tab traces 122 may receive structural support from the PV elements 140 while causing relatively little loss in efficiency of the PV element due to shadowing.

Thus, described herein are novel structures for a circuit substrate, methods for making such a circuit substrate, and electronic devices comprising a circuit substrate. While specific embodiments have been described herein, one skilled in the art will recognize that numerous variations and/or modifications may be implemented without departing from the teaching of this disclosure.

Reference in the specification to “one embodiment” or “an embodiment” means that a particular feature, structure, or characteristic described in connection with the embodiment is comprised in at least an implementation. The appearances of the phrase “in one embodiment” in various places in the specification are not necessarily all referring to the same embodiment.

What is claimed is:

1. A method to make a circuit substrate for an electronic device, comprising:
forming a plurality of circuit traces on a substrate, wherein at least a subset of the plurality of circuit traces comprise at least one tab trace excising a plurality of the tab traces from the substrate;
positioning at least one electronic component proximate at least one tab trace on the substrate, wherein the electrical component comprises at least one electrical contact on an upper surface of the component; and
inverting the tab trace to establish an electrical connection between an electrically conductive portion of the tab trace and an electrical contact on an upper surface of the at least one electronic component.

2. The method of claim 1, wherein forming a plurality of circuit traces on a flexible substrate comprises printing a plurality of circuit traces on the substrate.

3. The method of claim 1, wherein excising a plurality of the tabs from the substrate comprises cutting sections of the substrate proximate the at least one tab section.

4. The method of claim 1, wherein positioning at least one electronic component proximate at least one tab on the substrate comprises positioning the electronic component above the at least one tab section of the substrate.

5. The method of claim 1, wherein inverting the tab section to establish an electrical connection between an electrically conductive portion of the tab trace and an electrical contact on an upper surface of the at least one electronic component comprises rotating the tab traces about a longitudinal axis of the circuit trace

6. The method of claim 1, further comprising:
securing the at least one electrical component to the substrate.

7. A circuit substrate for and electronic device, comprising:
a substrate;
a plurality of circuit traces on a substrate, wherein at least a subset of the plurality of circuit traces comprise at least one tab trace, and a plurality of the tab traces are excised from the substrate.

8. The circuit substrate of claim 7, wherein the substrate comprises a flexible substrate material.

9. The circuit substrate of claim 7, wherein the plurality of circuit traces are printed on the substrate.

10. The circuit substrate of claim 7, further comprising at least one electrically insulating layer covering the plurality of circuit traces.

11. The circuit substrate of claim 10, wherein portions of the substrate are excised with the plurality of the tab traces.

11. The circuit substrate of claim 7, further comprising at least one electronic component positioned proximate at least one tab trace on the substrate, wherein the electrical component comprises at least one electrical contact on an upper surface of the component, and wherein the tab trace is inverted to establish an electrical connection between an electrically conductive portion of the tab trace and an electrical contact on an upper surface of the at least one electronic component.

12. The circuit substrate of claim 11, wherein a non-conductive portion of the at least one tab trace provides a physical restraint for an electronic component mounted on the circuit substrate.

13. The circuit substrate of claim 11, wherein the at least one electronic component comprises at least one of an integrated circuit, a power supply, an optical element, or an opto-electronic element.

13. An electronic device, comprising:
a substrate;
a plurality of circuit traces on a substrate, wherein at least a subset of the plurality of circuit traces comprise at least one tab trace, and a plurality of the tab traces are excised from the substrate; and
at least one electronic component positioned proximate at least one tab trace on the substrate, wherein the electrical component comprises at least one electrical contact on an upper surface of the component, and wherein the tab trace is inverted to establish an electrical connection between an electrically conductive portion of the tab trace and an electrical contact on an upper surface of the at least one electronic component.

14. The electronic device of claim 13, wherein the substrate comprises a flexible substrate material.

15. The electronic device of claim 13, wherein the plurality of circuit traces are printed on the substrate.

16. The electronic device of claim 13, further comprising at least one electrically insulating layer covering the plurality of circuit traces.

17. The electronic device of claim 13, wherein portions of the substrate are excised with the plurality of the tab traces.

18. The electronic device of claim 13, wherein a non-conductive portion of the at least one tab trace provides a physical restraint for an electronic component mounted on the circuit substrate.

19. The electronic device of claim 13, wherein the at least one electronic component comprises at least one of an integrated circuit, a power supply, an optical element, or an opto-electronic element.
